(19) United States
(12) Patent Application Publication
(10) Pub. No.: US 2002/0135406 A1
(43) Pub. Date: Sep. 26, 2002

(54) Controlled impedance driver receiving a combination binary and thermometer code

(76) Inventors: KM Mozammel Hossain, Fort Collins, CO (US); Gary L. Taylor, Windsor, CO (US)

Correspondence Address: HEWLETT-PACKARD COMPANY, Intellectual Property Administration, P.O. Box 272400, Fort Collins, CO, 80527-2400, US

(21) Appl. No.: 09/813,563

(22) Filed: Mar. 20, 2001

(51) Int. Cl. H03B 1/00

(52) U.S. Cl. 327/112

(57) ABSTRACT

An encoding for a set of PVT calibration signals that ensures monotonicity from code step to code step and also allows many of the drive transistors to be sized the same. A calibration signal encoding that is a combination of binary and thermometer codes is disclosed. A thermometer code is used to set a course value for the impedance of the driver and a binary code is used to fine-tune the output impedance. A driver/termination that receives this encoding is also disclosed. The driver/termination has transistors controlled by the binary portion of the encoding that are each approximately multiples of two in width-to-length ratio of each other. The driver/termination also has transistors controlled by the thermometer portion of the encoding that are each approximately the same width-to-length ratio.

### CROSS-REFERENCE TO RELATED APPLICATIONS

This application is related to another application filed on or about the same day as the present application. The related application is also owned by Hewlett-Packard corporation and is titled “COMBINATION BINARY AND THERMOMETER CODE FOR A CONTROLLED IMPEDANCE DRIVER” and has HP docket number 10011619-1.

### FIELD OF THE INVENTION

This invention relates generally to digital output drivers and termination impedances for integrated circuits. More particularly, it relates to a circuit and method for calibrating the drive or termination impedance of an integrated circuit output driver or controlled termination.

### BACKGROUND OF THE INVENTION

Dynamically calibrating the impedance of an output driver on an integrated circuit can have several advantages. It can reduce reflections on the output signal, reduce electromagnetic interference (EMI), reduce power dissipation, and reduce signal skew. Similar advantages can result from using dynamically calibrated drivers as termination impedances as well.

On a CMOS integrated circuit (IC), one way of controlling the impedance of an output driver is to split the pull-up transistor (typically a p-channel MOSFET (PFET) with it's source connected to the positive supply, VDD) and the pull-down transistor (typically a n-channel MOSFET (NFET) with it's source connected to the negative supply, GND) into multiple transistors. When the output driver is driving, each of these multiple transistors is then appropriately controlled to turn on, or remain off, according to a set of calibration signals such that the desired output impedance is achieved.

The set of calibration signals that control which of the multiple transistors are on are set to values that control a driver's impedance over process, voltage, and temperature (PVT). A commonly used encoding for the calibration signals is known as a binary (or binary-weighted) code.

Unfortunately, a binary code may cause a risk of a logic glitch as the code changes from one value to another. Another problem with a binary code is that the code bits are non-monotonic. Finally, a system using a binary code typically requires non-uniform sizes for the multiple transistors in the driver. This adds complexity in the design and characterization of the driver.

Accordingly, there is a need in the art for an improved system of encoding calibration a set of calibration signals such that the desired output impedance is achieved.

### SUMMARY OF THE INVENTION

A preferred embodiment of the invention receives an encoding for a set of PVT calibration signals that ensures monotonicity from code step to code step and also allows many of the drive transistors to be sized the same. Ensuring monotonicity helps prevent logic glitches as the calibration signals change from one value to another. Sizing many of the drive transistors the same helps simplify the tasks of design and characterization of the design. An embodiment of the invention receives a calibration signal encoding that is a combination of binary and thermometer codes. A thermometer code is used to set a course value for the impedance of the driver and a binary code is used to fine-tune the output impedance. Turning on and off a set of transistors that all have approximately the same width-to-length ratio sets the course value of the impedance. Fine-tuning of the output impedance is done by a set of transistors that have width-to-length ratios that are approximately multiples of two of each other.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is an illustration of a combination binary and thermometer code.

FIG. 2 is a schematic illustration of a controlled impedance driver/termination that uses a combination binary and thermometer code.

### DETAILED DESCRIPTION OF THE PREFERRED EMBODIMENTS

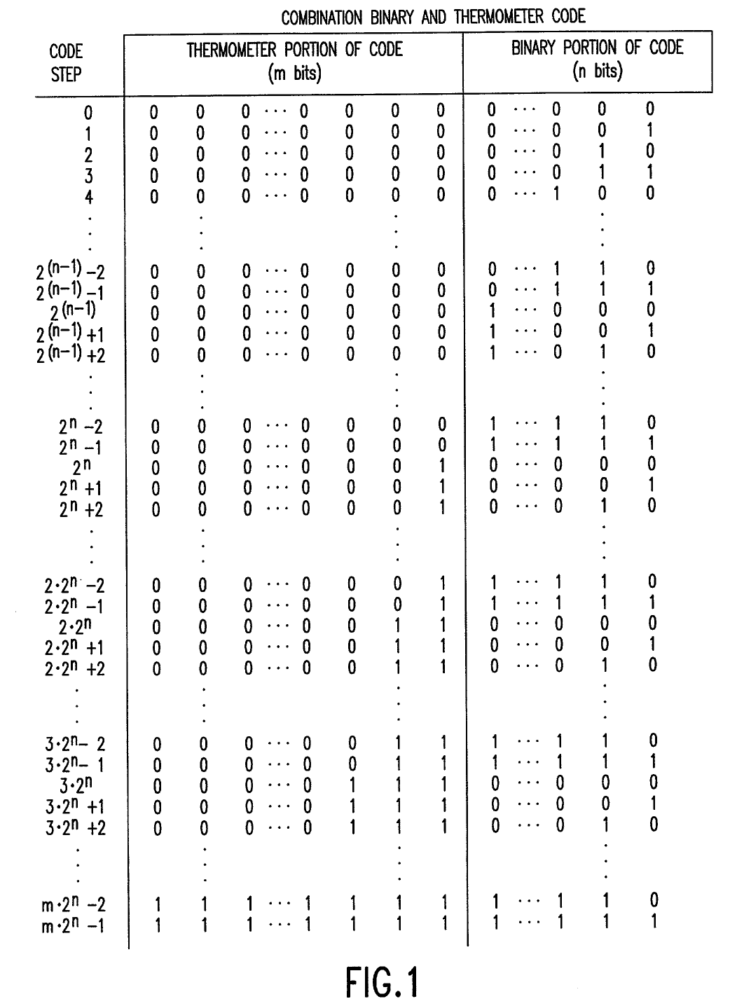

FIG. 1 is an illustration of a combination binary and thermometer code. FIG. 1 illustrates a combination binary and thermometer code with n bits of binary code and m bits of thermometer code. In a binary code each bit of the code is assigned a weight that is twice the bit of next least significance. (i.e. bit zero is assigned a weight of 1, bit one is assigned a weight of 2, bit two is assigned a weight of 4, etc.) In a thermometer code each bit is given equal weight. (i.e. bit zero is assigned a weight of 1, bit one is assigned a weight of 1, bit two is assigned a weight of 1, etc.) Accordingly, this combination code has m·2ⁿ unique code values.

As can be seen in FIG. 1, as the code step values increase, the binary code part of the combination code counts up in a standard binary counting fashion from all zeroes to all 1's. This is shown in FIG. 1 as code step values 0 to 2ⁿ-1. At the next code step, code step 2ⁿ, the binary code resets (or rolls over) to all zeroes again and the thermometer code sets a first bit. In FIG. 1, this is shown as the rightmost bit. However, it could be any bit since each bit in a thermometer code has equal weight. As the code step values increase, the binary code part of the combination code again counts up in a standard binary counting fashion from all zeroes to all 1's. This is shown in FIG. 1 as codes steps 2ⁿ to 2·2ⁿ−1. At the next code step, code step 2·2ⁿ−1, the binary code again rolls over to all zeroes. The thermometer code sets a second bit. In FIG. 1, this is shown as the next to rightmost bit. However, this could be any bit. This pattern continues for the rest of the code steps, steps 2ⁿ to m·2ⁿ−1, until all of the bits in both the binary and thermometer code are 1's.

In FIG. 1, code step zero is shown as corresponding to a combination code that is all zeroes and code step m·2ⁿ−1 corresponds to a combination code that is all ones. This for exemplary purposes only. The reverse could have been chosen where code step m·2ⁿ−1 corresponds to a combination code that is all zeroes and code step zero corresponds to a combination code that is all ones. Likewise, the number of code steps could have been chosen to start counting at 1 instead of zero.

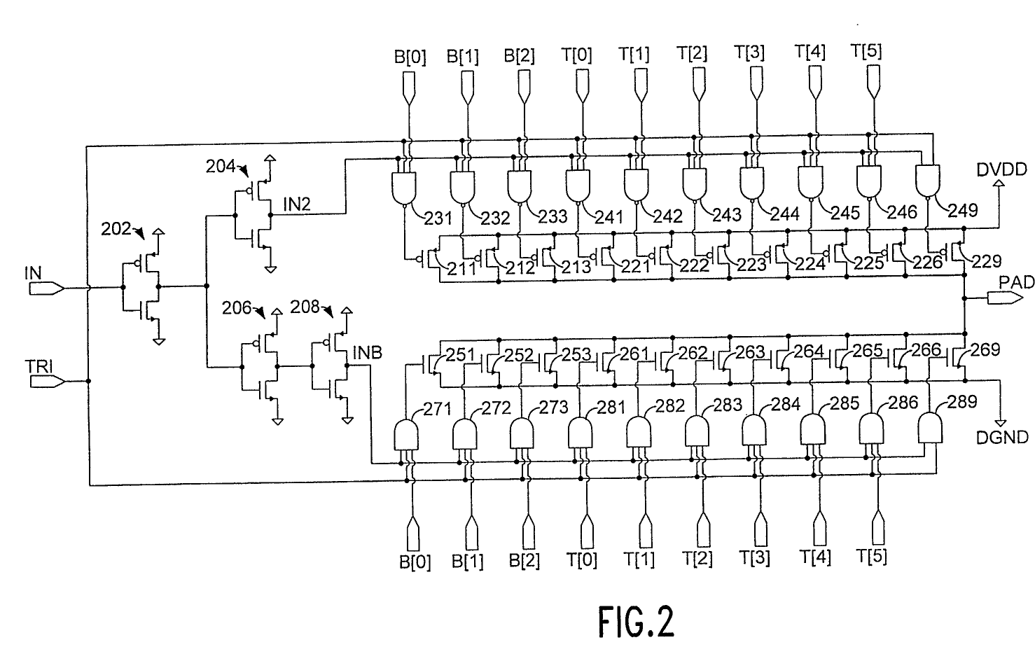

In a preferred embodiment, the combination code is generated by circuitry that is designed to sense variations in transistor characteristics and produce an output encoded in the combination code that is transmitted to other circuitry. The encoded information provided by the combination code may be used by the receiving circuitry to adjust a circuit parameter. Typically, this circuit parameter will be adjusted to compensate for variations in transistor characteristics caused by PVT variations. These types of adjustments work well with both bipolar and field-effect transistor circuits. FIG. 2 shows a circuit designed to receive the combination code that may be used either as an output driver with a controlled impedance or a controlled impedance termination (driver/termination). The circuit in FIG. 2 adjusts the width-to-length ratio of its output transistors in response to the combination code. If the information provided by the combination code to the circuit in FIG. 2 correlates to the width-to-length ratio needed to provide a particular impedance, the circuit shown in FIG. 2 can provide a controlled driving/termination impedance.

FIG. 2 is a schematic illustration of a controlled impedance driver/termination that uses a combination binary and thermometer code. The driver/termination shown in FIG. 2 receives a combination code with three binary bits (i.e. n=3) and six thermometer code bits (i.e. m=6). Accordingly, there are 6·2³=48 code steps in the code received by the driver/termination shown in FIG. 2. However, other values for m and n could be chosen depending upon a variety of design criteria such as impedance range and available area on a chip.

In FIG. 2, data input signal IN is buffered by inverters 202 and 204 to create signal IN2. IN is connected to the input of inverter 202. The output of inverter 202 is connected to the input of inverter 204. The output of inverter 204 is signal IN2. Data input is signal is also buffered and inverted by inverters 202, 206, and 208 to create signal INB. The output of inverter 202 is also connected to the input of inverter 206. The output of inverter 206 is connected to the input of inverter 208. The output of inverter 208 is signal INB.

Signal IN2 is connected to one input of three input NAND gates 231, 232, 233, 241, 242, 243, 244, 245, 246 and one input of two input NAND gate 249. Signal INB is connected to one input of three input AND gates 271, 272, 273, 281, 282, 283, 284, 285, 286 and one input of two input AND gates 289. Another input of NAND gates 231-233, 241-246, and 249 and AND gates 271-273, 281-286, and 289 are connected to input control signal TRI.

Code bits B[0] through B[2] of the combination code are connected to the third input of NAND gates 231-233, respectively. Code bits B[0] through B[2] are also connected to the third input of AND gates 271-273, respectively. Code bits T[0] through T[5] of the combination code are connected to the third input of NAND gates 241-246. Code bits T[0] through T[5] of the combination code are connected to the third input of AND gates 281-286.

The outputs of NAND gates 231-233, 241-246, and 249 are connected to the gates of p-channel field effect transistors (PFETs) 211-213, 221-226, and 229, respectively. The outputs of AND gates 271-273, 281-286, and 289 are connected to the gates of n-channel field effect transistors (NFETs) 251-253, 261-266, and 269, respectively. The drains of PFETs 211-213, 221-226, and 229 and the drains of NFETs 251-253, 261-266, and 269 are connected to output terminal PAD. The sources of PFETs 211-213, 221-226, and 229 are connected to a positive supply voltage DVDD. The sources of NFETs ) 251-253, 261-266, and 269 are connected to a negative supply voltage, DGND.

In a preferred embodiment, PFETs 241-246 all have approximately the same width-to-length ratio. Therefore PFETs 241-246 all have approximately the same conductance (and resistance) when on. Likewise, NFETs 261-266 all have approximately the same width-to-length ratio. Therefore NFETs 261-266 all have approximately the same conductance (and resistance) when on.

PFETs 213, 212, 211 each have approximately ½, ¼, and ⅛, respectively, the width-to-length ratio as PFETs 221-226. Accordingly, PFETs 211-213 each have a conductance that is approximately a multiple of 2 of each other and and PFETs 221-226 and therefore a resistance that is a multiple of 2 of each other and PFETs 221-226. NFETs 253, 252, 251 each have approximately ½, ¼, and ⅛, respectively, the width-to-length ratio as NFETs 261-266. Accordingly, NFETs 251-253 each have a conductance that is approximately a multiple of 2 of each other and NFETs 261-266 and therefore a resistance that is a multiple of ½ of each other and NFETs 261-266.

PFET 229 determines the maximum pull-up resistance of the driver/termination. Since it is not controlled by the combination code, PFET 229 is switched on and off independent of the value on the combination code. Likewise, NFET 269 determines the maximum pull-down resistance of the driver/termination. Since it is not controlled by the combination code, NFET 269 is switched on and off independent of the value on the combination code. In one embodiment, PFET 229 has a width-to-length ration that is approximately the same as the width-to-length ratios of PFETs 221-226 and NFET 269 has a width-to-length ration that is approximately the same as the width-to-length ratios of NFETs 261-266.

The driver/termination's output impedance is variable since the total width of on FETs is selectable by control signals B[0:2], T[0:5] that carry the combination code. Each time a control signal is activated (which, in this case, is going high) additional FET width is added to conducting a supply voltage to the output terminal, PAD. Likewise, each time a control signal is deactivated (which, in this case, is going low) FET width is subtracted from conducting a supply voltage to the output terminal.

The driver/termination shown in FIG. 2 receives a combination binary-weighted and thermometer weighted code to control the total width of FETs that are turned on. By using the combination code, the thermometer code part of the combination code sets a rough impedance value for driver/termination and the binary part of the code fine-tunes the impedance to provide precision.

Although a specific embodiment of the invention has been described and illustrated, the invention is not to be limited to the specific forms or arrangements of parts so described and illustrated. The invention is limited only by the claims.

What is claimed is:

1. A driver, comprising:
a first plurality of output transistors, said first plurality of transistors having conductances that are approximately multiples of two of each other;
a second plurality of output transistors, said second plurality of transistors having conductances that are approximately the same.

2. The driver of claim 1, wherein a set of control signals that affect whether said first plurality of transistors and said second plurality of transistors may be turned on comprises a binary code and a thermometer code.

3. The driver of claim 2, wherein said first plurality and second plurality of transistors are field-effect transistors and said first plurality of transistors have width-to-length ratios that are approximately multiples of two of each other.

4. The driver of claim 3 wherein said second plurality of transistors are field-effect transistors and said second plurality of transistors have width-to-length ratios that are approximately the same.

5. The driver of claim 1 further comprising:
a third plurality of output transistors, said first plurality of transistors having conductances that are approximately multiples of two of each other;
a fourth plurality of output transistors, said second plurality of transistors having conductances that are approximately the same.

6. The driver of claim 2 wherein said set of control signals communicates information that allow said first plurality of transistors and said second plurality of transistors maintain a controlled impedance when on.

7. A circuit for providing a controlled impedance, comprising:
a first plurality of transistors controlled by a binary code;
a second plurality of transistors controlled by a thermometer code.

8. The circuit of claim 7, wherein control of each of said first plurality of transistors comprises one bit of said binary code and the conductance of each of said first plurality of transistors corresponds to the significance of said one bit of said binary code that controls each of said first plurality of transistors.

9. The circuit of claim 8, wherein control of each of said second plurality of transistors comprises one bit of said thermometer code.

10. A controlled impedance driver, comprising:
a first transistor having a first conductance;
a second transistor having a second conductance that is approximately twice said first conductance;
a third transistor having a third conductance that is approximately twice said second conductance;
a plurality of fourth transistors each having a fourth conductance that is approximately twice said third conductance;
a first set of control signals carrying a binary code, said first set of control signals comprising a first signal that contributes to the control of said first transistor, a second signal that contributes to the control of said second transistor, and a third signal that contributes to the control of said third transistor; and,
a second set of control signals carrying a thermometer code wherein each signal of said second set of control signals contributes to the control of a single member of said plurality of fourth transistors.
